(19) United States
(12) Patent Application Publication
(10) Pub. No.: US 2002/0109222 A1
(43) Pub. Date: Aug. 15, 2002

(54) Multi-die integrated circuit package structure and method of manufacturing the same

(76) Inventors: Ya-Yi Lai, Taichung Hsien (TW); Kun-Ming Huang, Changhwa (TW)

Correspondence Address: Dike, Bronstein, Roberts & Cushman, Intellectual Property Practice Group, EDWARDS & ANGELL, P. O. Box 9169, Boston, MA, 02209, US

(21) Appl. No.: 09/579,589

(22) Filed: May 26, 2000

(51) Int. Cl. H01L 23/34

(52) U.S. Cl. 257/724

(57) ABSTRACT

A multi-die IC package structure and a method of manufacturing this multi-die IC package structure are proposed. This multi-die IC package structure is constructed on a lead frame including an inner-lead part having a plurality of inner leads surrounding a cavity in the center thereof, without the forming of a die pad. Next, a stacked multi-die structure is mounted on the inner-lead part of the lead frame, which is formed in such a manner the undermost semiconductor die has its non-circuit surface insulatively attached to the inner-lead part of the lead frame and its circuit surface insulatively attached to the overlying one, and also in such a manner that each of the semiconductor dies other than the undermost one has its non-circuit surface insulatively attached to the circuit surface of the underlying one. By the proposed method, the overall packaging process is significantly less complex than the prior art, thus allowing the manufacture process more cost-effective to carry out.

### BACKGROUND OF THE INVENTION

1. Field of the Invention

This invention relates to integrated circuit (IC) packaging technology, and more particularly, to a multi-die IC package structure and a method of manufacturing this multi-die IC package structure.

2. Description of Related Art

A multi-die IC package is a type of IC package that contains more than one semiconductor die therein, which can offer a manifold level of functionality than a single-die IC package. Conventionally, there are many ways to pack more than one semiconductor die in a single IC package, including, for example, the U.S. Pat. No. 5,545,922; and the Japanese Patent No. 56-62351 to Sano, 1981; to name just a few.

One drawback to the foregoing patents, however, is that they are quite complex in structure and thus require laborious processes to manufacture, which makes them costly to implement. For instance, in the case of dual-chip IC package, since the two semiconductor dies are mounted on opposite sides of the lead frame, it requires the lead frame to be first placed with one side up for a first round of die-bonding and wire-bonding process for the upside die and then turned upside down for a second round of die-bonding and wire-bonding process for the downside die. This requirement makes the overall manufacture process quite complex and thus costly to implement.

### SUMMARY OF THE INVENTION

It is therefore the primary objective of this invention to provide a new structure for multi-die IC package, which can be manufactured through a simplified process as compared to the prior art, so that the multi-die IC package structure can be manufactured in a more cost-effective manner than the prior art.

In accordance with the foregoing and other objectives, the invention proposes a new structure for multi-die IC package and a method of manufacture this multi-die IC package structure. The multi-die IC package structure of the invention comprises (a) a lead frame including an inner-lead part having a plurality of inner leads surrounding a cavity in the center thereof; (b) a plurality of semiconductor dies, each having a circuit surface and a non-circuit surface, which are stacked together to form a stacked multi-die structure in such a manner that the undermost one has its non-circuit surface insulatively attached to the inner-lead part of the lead frame and its circuit surface insulatively attached to the overlying one, and also in such a manner that each of the semiconductor dies other than the undermost one has its non-circuit surface insulatively attached to the circuit surface of the underlying one; (c) a plurality of sets of bonding wires, each set being used for electrically coupling one of the semiconductor dies to the lead frame; and (d) an encapsulation body for encapsulating the stacked multi-die structure.

Compared to the prior art, the multi-die IC package structure of the invention can be manufactured through a simplified process, making the manufacture process more cost-effective to carry out. The invention is therefore more advantageous to use than the prior art.

### BRIEF DESCRIPTION OF DRAWINGS

The invention can be more fully understood by reading the following detailed description of the preferred embodiments, with reference made to the accompanying drawings, wherein:

FIGS. 1A-1D are schematic sectional diagrams used to depict the procedural steps involved in the method of the invention for manufacturing a dual-die IC package, and

FIGS. 2A-2D are schematic sectional diagrams used to depict the procedural steps involved in the method of the invention for manufacturing a triple-die IC package.

### DETAILED DESCRIPTION OF PREFERRED EMBODIMENTS

The invention proposes a new multi-die IC package structure and a method of manufacturing this multi-die IC package structure. In the following detailed description, two embodiments of the invention will be disclosed, wherein the first embodiment is a dual-die IC package which contains two semiconductor dies, and the second embodiment is a triple-die IC package which contains three semiconductor dies.

It is to be noted that in the terminology of semiconductor technology, the term “chip” is synonymous with the term “die”. Moreover, the term “circuit surface” refers to the front side of a semiconductor die where circuit components and bonding pads are formed, while the term “non-circuit surface” refers to the back side opposite to the circuit surface.

First Preferred Embodiment (A Dual-DIE IC Package)

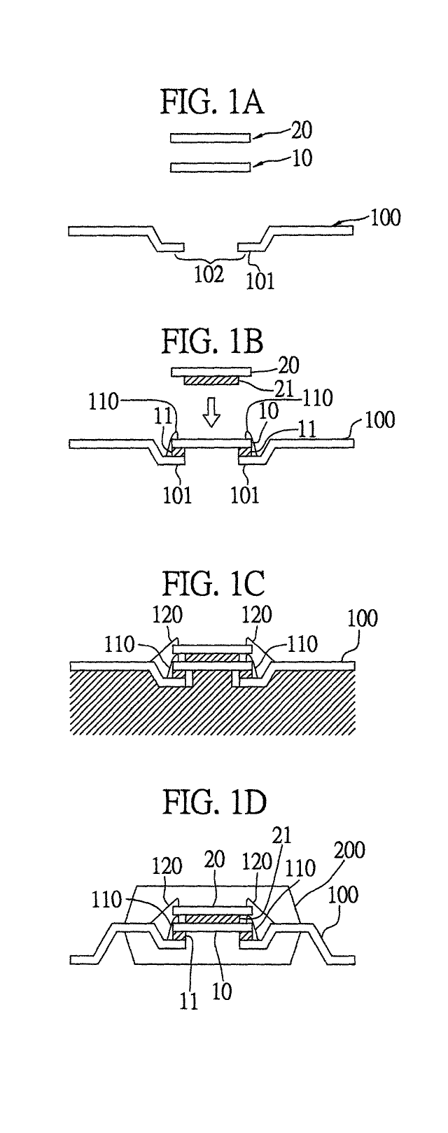

The first preferred embodiment of the invention is disclosed in full details in the following with reference to FIGS. 1A-1D. This embodiment is a dual-die IC package used to pack two semiconductor dies therein.

Referring first to FIG. 1A, in the manufacture process, the first step is to prepare two semiconductor dies, including a first semiconductor die 10 and a second semiconductor die 20. Further, a lead frame 100 is prepared, which includes an inner-lead part 101 having a plurality of inner leads surrounding a cavity 102 in the center of the lead frame 100. Compared to the prior art, this lead frame 100 is formed without a die pad.

Referring further to FIG. 1B, in the next step, a first die-bonding process is performed to attach the non-circuit surface of the first semiconductor die 10 onto the inner-lead part 101 of the lead frame 100 through the use of a non-Conductive Paste 11.

Next, a first wire-bonding process is performed to bond a first set of wires 110 for electrically coupling the first semiconductor die 10 to corresponding leads on the inner-lead part 101 of the lead frame 100. This wire-bonding process is a conventional technique, so detailed steps thereof will not be described.

Referring further to FIG. 1C, in the next step, a second die-bonding process is performed to attach the non-circuit surface of the second semiconductor die 20 onto the circuit surface of the first semiconductor die 10 through the use of a polyimide tape 21.

Next, a second wire-bonding process is performed to bond a second set of wires 120 for electrically coupling the second semiconductor die 20 to corresponding leads on the inner-lead part 101 of the lead frame 100.

Through the foregoing steps, a stacked dual-die structure is constructed over the inner-lead part 101 of the lead frame 100.

It is a characteristic feature of the invention that all the die-bonding and wire-bonding processes can be performed by fixing the lead frame without having to turn the lead frame upside down as in the case of the prior art. For this sake, the invention is undoubtedly more simplified in process than the prior art.

Referring next to FIG. 1D, in the subsequent step, an encapsulation process is performed to form an encapsulation body 200 to encapsulate the stacked dual-die structure therein. This encapsulation process is a conventional technique, so detailed steps thereof will not be further described. This completes the manufacture of a dual-die IC package in accordance with the invention.

Second Preferred Embodiment (A Triple-Die IC Package)

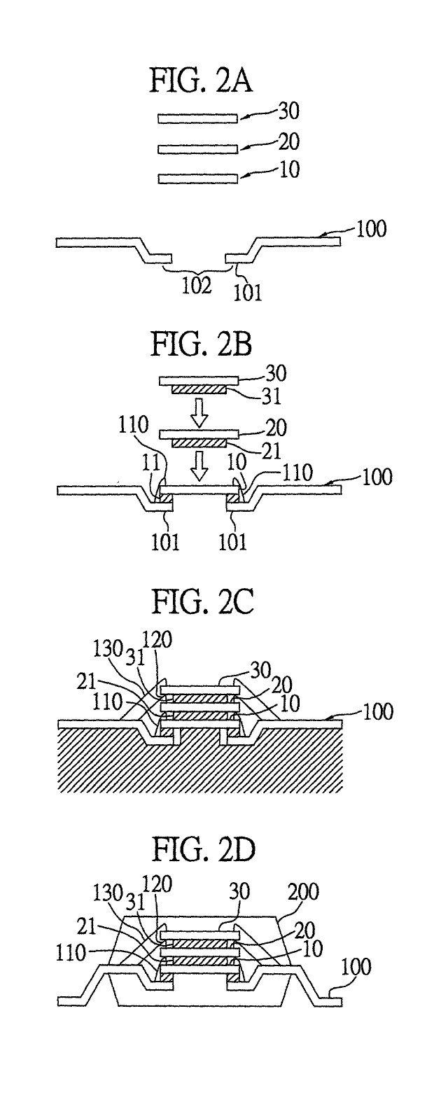

The second preferred embodiment of the invention is disclosed in full details in the following with reference to FIGS. 2A-2D. This embodiment is a triple-die IC package used to pack three semiconductor dies therein.

Referring first to FIG. 2A, in the manufacture process, the first step is to prepare three semiconductor dies, including a first semiconductor die 10, a second semiconductor die 20, and a third semiconductor die 30. Further, a lead frame 100 is prepared, which includes an inner-lead part 101 having a plurality of inner leads surrounding a cavity 102 in the center of the lead frame 100. Compared to the prior art, this lead frame 100 is formed without a die pad.

Referring further to FIG. 2B, in the next step, a first die-bonding process is performed to attach the non-circuit surface of the first semiconductor die 10 onto the inner-lead part 101 of the lead frame 100 through the use of a non-Conductive Paste 11.

Next, a first wire-bonding process is performed to bond a first set of wires 110 for electrically coupling the first semiconductor die 10 to corresponding leads on the inner-lead part 101 of the lead frame 100.

Referring further to FIG. 2C, in the next step, a second die-bonding process is performed to attach the non-circuit surface of the second semiconductor die 20 onto the circuit surface of the first semiconductor die 10 through the use of a polyimide tape 21.

Next, a second wire-bonding process is performed to bond a second set of wires 120 for electrically coupling the second semiconductor die 20 to corresponding leads on the inner-lead part 101 of the lead frame 100.

In the subsequent step, a third die-bonding process is performed to attach the non-circuit surface of the third semiconductor die 30 onto the circuit surface of the second semiconductor die 20 through the use of a polyimide tape 31.

Next, a third wire-bonding process is performed to bond a third set of wires 130 for electrically coupling the third semiconductor die 30 to corresponding leads on the inner-lead part 101 of the lead frame 100.

Through the foregoing steps, a stacked triple-die structure is constructed over the inner-lead part 101 of the lead frame 100.

It is a characteristic feature of the invention that all the die-bonding and wire-bonding processes can be performed by fixing the lead frame without having to turn the lead frame upside down as in the case of the prior art. For this sake, the invention is undoubtedly more simplified in process than the prior art.

Referring next to FIG. 2D, in the subsequent step, an encapsulation process is performed to form an encapsulation body 200 to encapsulate the stacked triple-die structure therein. This encapsulation process is a conventional technique so detailed steps thereof will not be further described. This completes the manufacture of a triple-die IC package in accordance with the invention.

Conclusion

The foregoing two embodiments are respectively a dual-chip IC package and a triple-chip IC package, which are both manufactured in accordance with the method of the invention. The invention, however, is not limited to these two embodiments, and instead is broadly defined as a multi-die IC package structure which can be used pack two, three, or more semiconductor dies. These semiconductor dies are stacked together to form a stacked multi-die structure in such a manner that the undermost one has its non-circuit surface insulatively attached to the inner-lead part of the lead frame and its circuit surface insulatively attached to the overlying one, and also in such a manner that each of the semiconductor dies other than the undermost one has its non-circuit surface insulatively attached to the circuit surface of the underlying one.

Compared to the prior art, the multi-die IC package structure of the invention can be manufactured through a simplified process, making the manufacture process more cost-effective to carry out. Moreover, since the lead frame has no die pad, it can help prevent the problem of delamination. Still moreover, compared to the prior art of U.S. Pat. No. 5,545,922, the invention can be implemented without having to turn the lead frame upside down, and therefore is easier and more cost-effective to implement than the U.S. Pat. No. 5,545,922. The invention is therefore more advantageous to use than the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A multi-die IC package structure, which comprises:
a lead frame including an inner-lead part having a plurality of inner leads surrounding a cavity in the center thereof;
a plurality of semiconductor dies, each having a circuit surface and a non-circuit surface, which are stacked together to form a stacked multi-die structure in such a manner that the undermost one has its non-circuit surface insulatively attached to the inner-lead part of the lead frame and its circuit surface insulatively attached to the overlying one, and also in such a manner that each of the semiconductor dies other than the undermost one has its non-circuit surface insulatively attached to the circuit surface of the underlying one;
a plurality of sets of bonding wires, each set being used for electrically coupling one of the semiconductor dies to the lead frame; and
an encapsulation body for encapsulating the stacked multi-die structure.

2. The multi-die IC package structure of claim 1, wherein a non-Conductive Paste is used to attach the undermost semiconductor die to the inner-lead part of the lead frame.

3. The multi-die IC package structure of claim 1, wherein a polyimide tape is used to attach each of the semiconductor dies other than the undermost semiconductor die to the underlying one in the stacked multi-die structure.

4. A method for manufacturing a multi-die IC package, comprising the steps of:
(1) preparing a plurality of semiconductor dies each having a circuit surface and a non-circuit surface;
(2) preparing a lead frame including an inner-lead part having a plurality of inner leads surrounding a cavity in the center thereof;
(3) forming a stacked multi-die structure over the inner-lead part of the lead frame by arranging the plurality of semiconductor dies in such a manner that the undermost one has its non-circuit surface insulatively attached to the inner-lead part of the lead frame and its circuit surface insulatively attached to the overlying one, and each of the semiconductor dies other than the undermost one has its non-circuit surface insulatively attached to the circuit surface of the underlying one; with each semiconductor die being connected via a dedicated set of bonding wires to corresponding points on the lead frame; and
(4) forming an encapsulation body for encapsulating the stacked multi-die structure.

5. The method of claim 4, wherein in said step (3), a non-Conductive Paste is used to attach the undermost semiconductor die to the inner-lead part of the lead frame.

6. The method of claim 5, wherein in said step (3), a polyimide tape is used to attach each of the semiconductor dies other than the undermost semiconductor die to the underlying one in the stacked multi-die structure.

7. A method for manufacturing a dual-die IC package, comprising the steps of
(1) preparing a first semiconductor die and a second semiconductor die, each semiconductor die having a circuit surface and a non-circuit surface;
(2) preparing a lead frame including an inner-lead part having a plurality of inner leads surrounding a cavity in the center thereof;
(3) performing a first die-bonding process for insulatively attaching the non-circuit surface of the first semiconductor die onto the inner-lead part of the lead frame;
(4) performing a first wire-bonding process for electrically coupling the first semiconductor dies to the lead frame;
(5) performing a second die-bonding process for insulatively attaching the non-circuit surface of the second semiconductor die onto the circuit surface of the first semiconductor die;
(6) performing a second wire-bonding process for electrically coupling the second semiconductor dies to the lead frame; and
(7) forming an encapsulation body for encapsulating the first and second semiconductor dies.

8. The method of claim 7, wherein in said step (3), a non-Conductive Paste is used to attach the first semiconductor die to the inner-lead part of the lead frame.

9. The method of claim 7, wherein in said step (5), a polyimide tape is used to attach the second semiconductor die to the first semiconductor die.
